(19) United States
(12) Patent Application Publication
(10) Pub. No.: US 2025/0089300 A1
(43) Pub. Date: Mar. 13, 2025

(54) OXIDE THIN FILM TRANSISTOR

(71) Applicant: ELECTRONICS AND TELECOMMUNICATIONS RESEARCH INSTITUTE, Daejeon (KR)

(72) Inventors: Yong Hae KIM, Daejeon (KR); Chi-Sun HWANG, Daejeon (KR); Jong-Heon YANG, Daejeon (KR); Seong-Mok CHO, Daejeon (KR); Jae-Eun PI, Daejeon (KR)

(21) Appl. No.: 18/767,665

(22) Filed: Jul. 9, 2024

(30) Foreign Application Priority Data
Sep. 12, 2023 (KR) 10-2023-0121138

(51) Int. Cl. H01L 29/786; H01L 23/14; H01L 29/24; H01L 29/417; H01L 29/45

(52) U.S. Cl. CPC H10D 30/6755; H10D 30/6729; H10D 62/80; H10D 64/62; H01L 23/14

(57) ABSTRACT

Provided is an oxide thin film transistor. The transistor includes a gate electrode on a center of a substrate, an active layer provided on the gate electrode and the substrate and including a metal oxide, and a source electrode and a drain electrode provided on the active layer, which is on both sides of the gate electrode. The source electrode and the drain electrode may each include a first metal layer and a second metal layer on the first metal layer.

### CROSS-REFERENCE TO RELATED APPLICATIONS

This U.S. non-provisional patent application claims priority under 35 U.S.C. § 119 of Korean Patent Application No. 10-2023-0121138, filed on Sep. 12, 2023, the entire contents of which are hereby incorporated by reference.

### BACKGROUND

The present disclosure herein relates to a thin film transistor and more particularly, to an oxide thin film transistor.

Generally, in order to manufacture a panel using an oxide thin film transistor, a channel length thereof may need to be shortened. Similarly in MOSFET, when a channel length of an oxide thin film transistor is reduced to a several μm scale, a threshold voltage may decrease, and short-channel effects may be caused. Reasons of the short-channel effects are various and methods for mitigating the same may vary depending on the reasons.

### SUMMARY

The present disclosure provides an oxide thin film transistor capable of decreasing or minimizing short-channel effects.

An embodiment of the inventive concept provides an oxide thin film transistor. The transistor is provided on a gate electrode on a center of a substrate, an active layer provided on the gate electrode and the substrate and including a metal oxide, and a source electrode and a drain electrode provided on the active electrode of both sides of the gate electrode. Herein, the source electrode and the drain electrode may each include a first metal layer, and a second metal layer on the first metal layer.

In an embodiment, the first metal layer may include tungsten.

In an embodiment, the second metal layer may include a barrier metal layer.

In an embodiment, the second metal layer may include titanium.

In an embodiment, the second metal layer may further include tungsten.

In an embodiment, the second metal layer may include titanium and tungsten at a component ratio of 1:9.

In an embodiment, the active layer may include InGaZnO.

In an embodiment, a gate insulation layer may be further included between the gate electrode and the active layer.

In an embodiment, the gate insulation layer may be an oxide thin film transistor including a dielectric material.

In an embodiment, the substrate may include a silicon wafer, glass, or plastic.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view illustrating an oxide thin film transistor according to an embodiment of the inventive concept;

FIG. 2 is a cross-sectional view illustrating an active layer and a source electrode in FIG. 1 according to an embodiment;

FIG. 3 is a graph showing Gibbs formation energy according to temperatures of a source electrode and titanium;

FIG. 4 is a graph showing Gibbs formation energy according to temperatures of an active layer and tungsten;

FIG. 5 is a cross-sectional view illustrating the active layer and source electrode in FIG. 1 according to an embodiment; and

FIG. 6 is a cross-sectional view illustrating the active layer and source electrode in FIG. 1 according to an embodiment.

### DETAILED DESCRIPTION

Hereinafter, the present invention will be explained in detail with reference to the accompanying drawings. The advantages and features of the present inventive concept and methods for achieving the same will be clear by referring to the embodiments described in detail below with reference to the accompanying drawings. However, the present inventive concept is not limited to the embodiments described herein and may be embodied in different forms. Rather, the embodiments introduced herein are provided so that the disclosed content will be thorough and complete and so that the spirit of the inventive concept can be sufficiently conveyed to those skilled in the art, and the inventive concept is defined only by the scope of the claims. The same reference numerals and symbols refer to the same elements throughout the specification.

The terminology used herein is to describe embodiments and is not intended to be limiting the inventive concept. As used herein, the singular forms also include the plural forms unless the context particularly indicates otherwise. The terms “comprises” and/or “comprising” when used in this specification, the stated components, operations, and/or elements do not preclude the presence or addition of one or more other components, operations, and/or elements. In addition, since this is according to a preferred embodiment, reference numerals and symbols presented according to the order of description are not necessarily limited to that order.

In addition, the embodiments described in this specification will be described with reference to cross-sectional views and/or plan views, which are ideal illustrations. The thickness of films and regions are exaggerated for effective description of the technical contents. Therefore, the form of the illustration may be modified depending on manufacturing technology, tolerance, and/or the like. Accordingly, embodiments of the present inventive concept are not limited to the specific form shown but also include changes in form produced according to the manufacturing process.

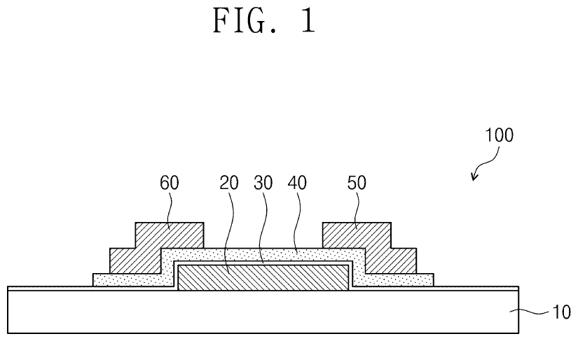

FIG. 1 illustrates an oxide thin film transistor 100 according to the inventive concept.

Referring to FIG. 1, the oxide thin film transistor 100 according to the inventive concept may include a substrate 10, a gate electrode 20, a gate insulation film 30, an active layer 40, a source electrode 50, and a drain electrode 60.

The substrate 10 may include a silicon wafer. Alternatively, the substrate 10 may include glass or plastic, but an embodiment of the inventive concept is not limited thereto.

The gate electrode 20 may be provided on a center of the substrate 10. The gate electrode 20 may include a metal such as gold (Au), silver (Ag), copper (Cu), aluminum (Al), tungsten (W), titanium (Ti), or molybdenum (Mo). Alternatively, the gate electrode 20 may include a silicon layer doped with impurities, but an embodiment of the inventive concept is not limited thereto.

The gate insulation film 30 may be provided on the gate electrode 20 and the substrate 10. The gate insulation film 30 may be removed or omitted. The gate insulation film 30 may include a dielectric material of a silicon oxide or a silicon nitride. Alternatively, the gate insulation film 30 may include a rare earth oxide such as hafnium oxide, or yttrium oxide, but an embodiment of the inventive concept is not limited thereto.

The active layer 40 may be provided on the gate insulation film 30 of the gate electrode 20. The active layer 40 may include a metal oxide or a semiconductor oxide. For example, the active layer 40 may include InGaZnO.

The source electrode 50 may be provided on one side of the active layer 40.

The drain electrode 60 may be provided on the other side of the active layer 40 opposite to the source electrode 50.

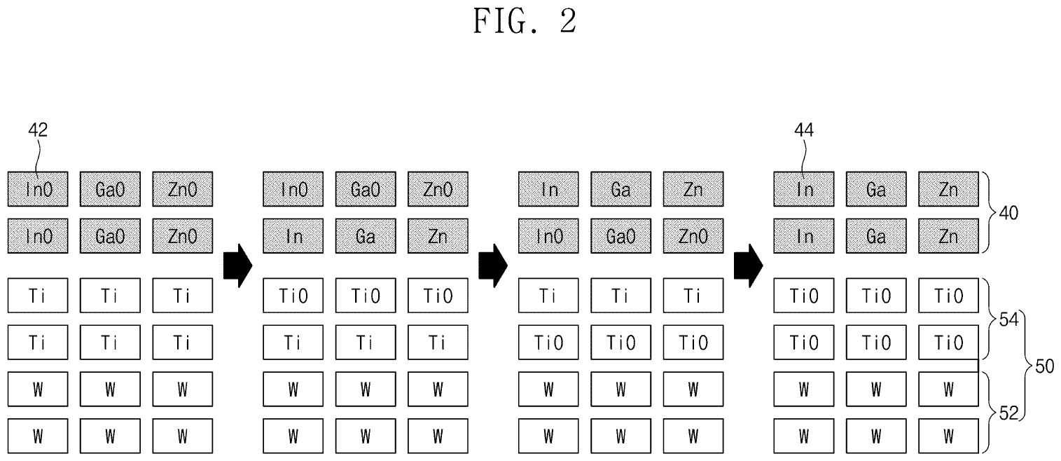

FIG. 2 illustrates the active layer 40 and the source electrode 50 in FIG. 1 according to an embodiment.

Referring to FIG. 2, the active layer 40 may include metal oxide molecules 42.

The metal oxide molecules 42 of the active layer 40 may include indium oxide (InO), gallium oxide (GaO), and zinc oxide (ZnO). The metal oxide molecules 42 of the active layer 40 may be reduced to metal components 44 by high heat of at least 300° C. The metal components 44 may include indium (In), gallium (Ga), and zinc (Zn). Oxygen may be diffused into or penetrate the source electrode 50 and the drain electrode 60.

Referring to FIG. 2 again, the source electrode 50 may include a first metal layer 52 and a second metal layer 54.

The first metal layer 52 may be provided below the second metal layer 54. The first metal layer 52 may have oxidation resistance. For example, the first metal layer 52 may include tungsten (W).

The second metal layer 54 may be provided between the first metal layer 52 and the active layer 40. The second metal layer 54 may include a barrier metal layer. For example, the second metal layer 54 may include titanium (Ti). The second metal layer 54 may be oxidized by heat. When the active layer 40 and the source electrode 50 are heated at a temperature of at least about 300° C., the second metal layer 54 may be oxidized by oxygen diffused from the active layer 40. The second metal layer 54 may be transformed to a titanium oxide (TiO) layer by the oxidation.

Referring to FIG. 1 and FIG. 2, the drain electrode 60 may be similarly constituted to the source electrode 50. Although not illustrated, the drain electrode 60 may include the first metal layer 52 and the second metal layer 54.

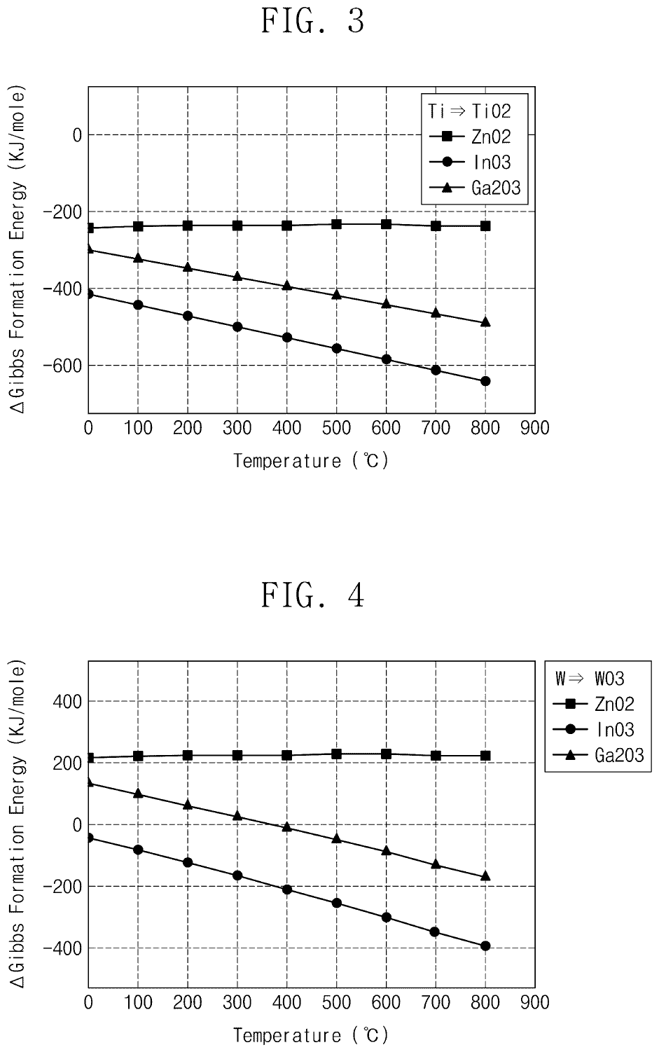

FIG. 3 shows Gibbs formation energy according to temperatures of the source electrode 50 and titanium (Ti).

Referring to FIG. 3, titanium (Ti) may react with the active layer 40 due to Gibbs formation energy of a negative value. The second metal layer 54 of titanium (Ti) may be converted or form a titanium oxide (TiO) layer. The second metal layer 54 may function as a barrier metal oxide film to suppress an oxidation reaction of the first metal layer 52. That is, titanium oxide (TiO) may prevent from reacting to tungsten oxide (WO₃). Titanium oxide (TiO) may be used as the source electrode 50 and the drain electrode 60 of a conductive layer. However, titanium oxide (TiO) may cause resistance of the second metal layer 54. The second metal layer 54 needs to be thinned to a single atomic layer thickness, but defects generated during the process may cause a connection between the active layer 40 and the first metal layer 52 of an oxide semiconductor.

FIG. 4 shows Gibbs formation energy according to temperatures of the active layer 40 and tungsten (W) in FIG. 2.

Referring to FIG. 4, indium oxide (InO) may convert tungsten (W) to tungsten oxide (WO₃), but gallium oxide (GaO) may not convert tungsten (W) to tungsten oxide (WO₃). Therefore, the second metal layer 54 may include tungsten (W).

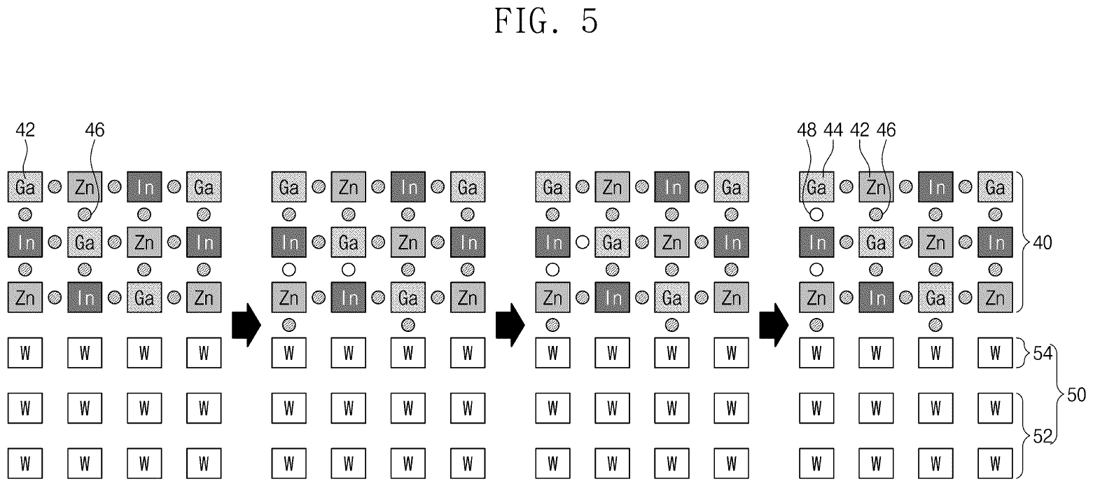

FIG. 5 illustrates the active layer 40 and the source electrode 50 in FIG. 1 according to an embodiment.

Referring to FIG. 5, the second metal layer 54 of the source electrode 50 may include tungsten (W). The active layer 40 may have, due to high heat, a metal component 44 and an oxygen vacancy 48. Nevertheless, the second metal layer 54 of tungsten (W) may not react or be oxidized due to oxygen 46 in the active layer 40. Therefore, the second metal layer 54 of tungsten (W) may prevent and minimize short-channel effects.

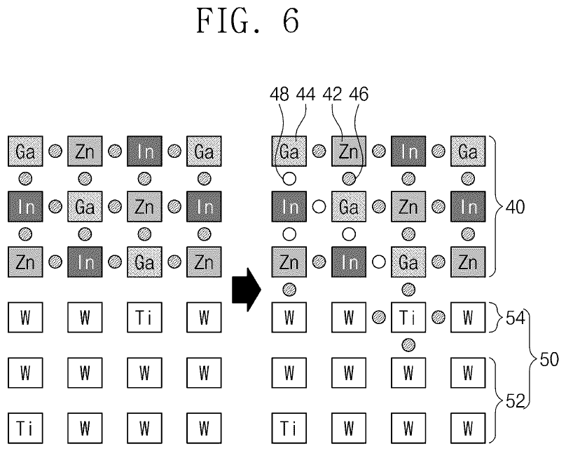

FIG. 6 illustrates the active layer 40 and the source electrode 50 in FIG. 1 according to an embodiment.

Referring to FIG. 6, the second metal layer 54 of the source electrode 50 may include tungsten (W) and titanium (Ti). The second metal layer 54 may contain titanium (Ti) and tungsten (W) at a component ratio or weight ratio of about 1:9. Titanium (Ti) may control oxygen vacancy generation and may increase a connection property to the active layer 40.

Therefore, the oxide thin film transistor 100 according to the inventive concept may decrease or minimize the short-channel effects using the source electrode 50 and the drain electrode 60 containing titanium (Ti) and tungsten (W).

As described above, the oxide thin film transistor according to the inventive concept may decrease or minimize the short-channel effects using the source electrode and the drain electrode containing titanium and tungsten.

Hitherto, although the embodiments of the inventive concept have been described with reference to the accompanying drawings, a person ordinary skilled in the art to which the present inventive concept pertains will understand that the present inventive concept can be implemented in other specific forms without changing technical idea or essential features thereof. Therefore, it should be understood that the embodiments described above are illustrated as examples in all aspects, and an embodiment of the inventive concept is not limited thereto.

What is claimed is:

1. An oxide thin film transistor comprising:
a gate electrode on a center of a substrate;
an active layer provided on the gate electrode and the substrate, the active layer including a metal oxide; and
a source electrode and a drain electrode provided on the active layer of both sides of the gate electrode,
wherein each of the source electrode and the drain electrode includes a first metal layer; and a second metal layer on the first metal layer.

2. The oxide thin film transistor of claim 1, wherein the first metal layer comprises tungsten.

3. The oxide thin film transistor of claim 1, wherein the second metal layer comprises a barrier metal layer.

4. The oxide thin film transistor of claim 1, wherein the second metal layer comprises titanium.

5. The oxide thin film transistor of claim 1, wherein the second metal layer further comprises tungsten.

6. The oxide thin film transistor of claim 1, wherein the second metal layer comprises titanium and tungsten at a component ratio of 1:9.

7. The oxide thin film transistor of claim 1, wherein the active layer comprises InGaZnO.

8. The oxide thin film transistor of claim 1, further comprising a gate insulation film between the gate electrode and the active layer.

9. The oxide thin film transistor of claim 8, wherein the gate insulation film comprises a dielectric material.

10. The oxide thin film transistor of claim 1, wherein the substrate comprises a silicon wafer, glass, or plastic.
